(19) United States
(12) Patent Application Publication
(10) Pub. No.: US 2014/0034358 A1
(43) Pub. Date: Feb. 6, 2014

(54) ELECTRODE PATTERN AND METHOD OF MANUFACTURING THE SAME, PRINTED CIRCUIT BOARD USING ELECTRODE PATTERN AND METHOD OF MANUFACTURING THE SAME

(71) Applicant: Samsung Electro-Mechanics Co., Ltd., Gyeonggi-do (KR)

(72) Inventors: Kwang Jik Lee, Gyeonggi-do (KR); Sang Hyun Shin, Gyeonggi-do (KR); Hye Suk Shin, Gyeonggi-do (KR); Joon Seok Kang, Gyeonggi-do (KR)

(73) Assignee: Samsung Electro-Mechanics Co., Ltd., Gyeonggi-do (KR)

(21) Appl. No.: 13/956,302

(22) Filed: Jul. 31, 2013

(30) Foreign Application Priority Data
Aug. 2, 2012 (KR) 10-2012-0084842

(51) Int. Cl. H05K 1/02; H05K 3/02

(52) U.S. Cl. CPC H05K 1/0271; H05K 3/02
USPC 174/251; 205/125

(57) ABSTRACT

Disclosed herein are an electrode pattern and a method of manufacturing the same, and a printed circuit board applied with the electrode pattern and a method of manufacturing the same. In order to increase a heat dissipation effect, disclosed herein are an electrode pattern including electrode layers with a predetermined pattern; and insulators insulating the electrode layers from each other, in which the insulators are made of metal oxide, a method of manufacturing the same, and a printed circuit board applied with the electrode pattern and a method of manufacturing the same.

### CROSS REFERENCE(S) TO RELATED APPLICATIONS

This application claims the benefit under 35 U.S.C. Section 119 of Korean Patent Application Serial No. 10-2012-0084842, entitled “Electrode Pattern and Method of Manufacturing the Same, Printed Circuit Board Using Electrode Pattern and Method of Manufacturing the Same” filed on Aug. 2, 2012, which is hereby incorporated by reference in its entirety into this application.

### BACKGROUND OF THE INVENTION

1. Technical Field

The present invention relates to an electrode pattern with metal oxide between electrode layers and a method of manufacturing the same, a printed circuit board using the electrode pattern and a method of manufacturing the same.

2. Description of the Related Art

In general, a printed circuit board (PCB) is manufactured by configuring a minute electrode layer and forming a hole for attaching and mounting components after attaching a thin plate such as copper, and the like on one surface of a phenol resin insulating plate or an epoxy resin insulating plate. The printed circuit board keeps a plurality of electronic components, and serves to electrically connect mounted electronic components to each other and insulating adjacent circuits from each other.

In recent years, with rapid spread of light, thin, short, and small mobile communication equipment and electronic products, a technology of the printed circuit board has been also rapidly changed to products having multi-layer high-concentration and multifunctions. In particular, a heat radiation problem has come to the fore as the most important problem in an audio power module, a PDP power module, a motor controller, an LED illumination, a light emitting diode back light unit (LED BLU), a thermoelectric material, and a high-power semiconductor device field, and when an effective heat dissipating structure is not adopted, a problem in reliability of the product occurs.

FIG. 1 is a cross-sectional view illustrating a frame retardant (FR)-4 printed circuit board which is a printed circuit board in the related art.

As illustrated in the figure, the FR-4 printed circuit board in the related art has a structure of an insulating layer 130 between a mother substrate 110 and a copper electrode layer 120. In more detail, the insulating layer 130 is manufactured by immersing epoxy 131 in a glass fiber 132 prepared by crossing a line of latitude and a line of longitude as if cloth is woven. A copper clad laminate (CCL) is manufactured by vacuum thermocompressing an electrolytic copper foil onto both surfaces of the insulating layer 130 at the time of manufacturing the PCB with the insulating layer 130 being made in a sheet type, and the electrode layer 120 with a printed electrode layer is formed by using a photo process. The photo process is generally constituted by processes of photoresist application, exposure, etching, photoresist stripping, and the like, and since the photo process is a known technique in a PCB industry, the corresponding photo process is called a photo process hereinbelow.

In the general FR-4 PCB, the thickness of the insulating layer 130 is approximately 75 μm or more, and since thermal conductivity of the glass fiber 132 and the epoxy 131 is generally very low as 0.25 W/mK, the general FR-4 PCB is inappropriate to use for an LED and a PCB for a high-power semiconductor device.

As a result, in order to increase the thermal conductivity, metal or an alloy having excellent thermal conductivity is generally used as the mother substrate and an alumina insulating layer is manufactured on the metal (for example, aluminum) mother substrate by using anodizing (Korean Patent Laid-Open Publication No. 10-2012-0048380, hereinafter, Related Art Document).

Since alumina (Al₂O₃) has excellent in insulating property and thermal conductivity, an excellent heat dissipation effect is acquired as well as ensuring the insulating property between the mother substrate and the electrode layer even though the thickness of alumina (Al₂O₃) is small.

However, no matter what a general resin is used as the insulating layer or the alumina insulating layer is used as the insulating layer, the photo process constituted by the processes of the photoresist application, exposure, etching, photoresist stripping, and the like needs to be performed in order to form the electrode layer on the insulating layer. Since this photo process is complicated, a production cost increases and productivity deteriorates.

In addition, since the electrode layer is adhered to the insulating layer only by the bottom of the electrode layer in the structure of the related art document, adhesion power between the electrode layer and the insulating layer is considerably decreased, and as a result, the reliability of the product deteriorates.

Further, even though the alumina insulating layer having excellent thermal conductivity is used in the related art document, heat generated from the device is transferred to the insulating layer only through the bottom of the electrode layer. Therefore, a bottleneck phenomenon occurs at an adhered portion of the electrode layer and the insulating layer due to a narrow heat movement route, and as a result, heat is not efficiently dissipated.

### SUMMARY OF THE INVENTION

An object of the present invention is to provide an electrode pattern with insulators made of metal oxide, which are provided between electrode layers and a method of manufacturing the same, and a printed circuit board applied with an electrode pattern and a method of manufacturing the same.

According to an exemplary embodiment of the present invention, there is provided an electrode pattern, including: electrode layers having a predetermined pattern; and insulators insulating the electrode layers from each other, wherein the insulators are made of metal oxide.

The insulators may be made of metal oxide formed by oxidizing the same material as the electrode layers.

The insulators may be regions oxidized in a metallic layer, and the electrode layers may be regions not oxidized in the metallic layer.

The insulators may contain any one or two or more of alumina (Al₂O₃), magnesium oxide (MgO), manganese oxide (MnO), zinc oxide (ZnO), titanium oxide (TiO₂), hafnium oxide (HfO₂), tantalum oxide (Ta₂O₅), and niobium oxide (Nb₂O₃).

The electrode layer may be made of a metallic material which is anodized.

The electrode layers may contain any one or two or more of aluminum (Al), magnesium (Mg), manganese (Mn), zinc (Zn), titanium (Ti), hafnium (Hf), tantalum (Ta), and niobium (Nb).

The electrode layer may have the same thickness as the insulator. According to another exemplary embodiment of the present invention, there is provided a method of manufacturing an electrode pattern, including: forming a metallic layer; attaching a mask with a predetermined pattern onto the surface of the metallic layer; forming electrode layers and insulators insulating the electrode layers from each other by oxidizing the metallic layer exposed through an opening on the mask; and removing the mask.

The predetermined pattern formed on the mask may be the same as a pattern of the electrode layer.

The predetermined pattern of the mask may be formed through a photo process.

The metallic layer may be made of a metallic material which is anodized.

The metallic layer may contain any one or two or more of aluminum (Al), magnesium (Mg), manganese (Mn), zinc (Zn), titanium (Ti), hafnium (Hf), tantalum (Ta), and niobium (Nb).

The metallic layer may be formed by any one process of sputtering, plating, thermal deposition, e-beam deposition, physical vapor deposition (PVD), and chemical vapor deposition (CVD).

The oxidizing may use an anodizing method or a plasma electrolytic oxidation method.

According to yet another exemplary embodiment of the present invention, there is provided a printed circuit board, including: a mother substrate; an insulating layer formed on one surface or both surfaces of the mother substrate; electrode layers formed on the insulating layer and having a predetermined pattern; and insulators insulating the electrode layers from each other, wherein the insulators are made of metal oxide.

The mother substrate may be made of a metallic material which is anodized.

The insulating layer may be made of metal oxide.

According to still another exemplary embodiment of the present invention, there is provided a method of manufacturing a mother substrate, including: preparing a mother substrate; forming an insulating layer on one surface or both surfaces of the mother substrate; forming a metallic layer on the insulating layer; attaching a mask with a predetermined pattern onto the surface of the metallic layer; forming electrode layers and insulators insulating the electrode layers from each other by oxidizing the metallic layer exposed through an opening on the mask; and removing the mask.

The insulating layer may be formed by oxidizing the mother substrate.

### BRIEF DESCRIPTION OF THE DRAWINGS

FIG. 1 is a cross-sectional view of a printed circuit board in the related art.

FIG. 2 is a cross-sectional view of an electrode pattern according to the present invention.

FIG. 3 is another exemplary embodiment of an electrode pattern according to the present invention.

FIG. 4 is a flowchart of a method of manufacturing an electrode pattern according to the present invention.

FIG. 5 is a cross-sectional view of a printed circuit board applied with the electrode pattern of the present invention.

FIGS. 6 and 7 are other exemplary embodiments of the printed circuit board applied with the electrode pattern of the present invention.

FIGS. 8 through 12 are flowcharts of a method of manufacturing the printed circuit board applied with the electrode pattern of the present invention.

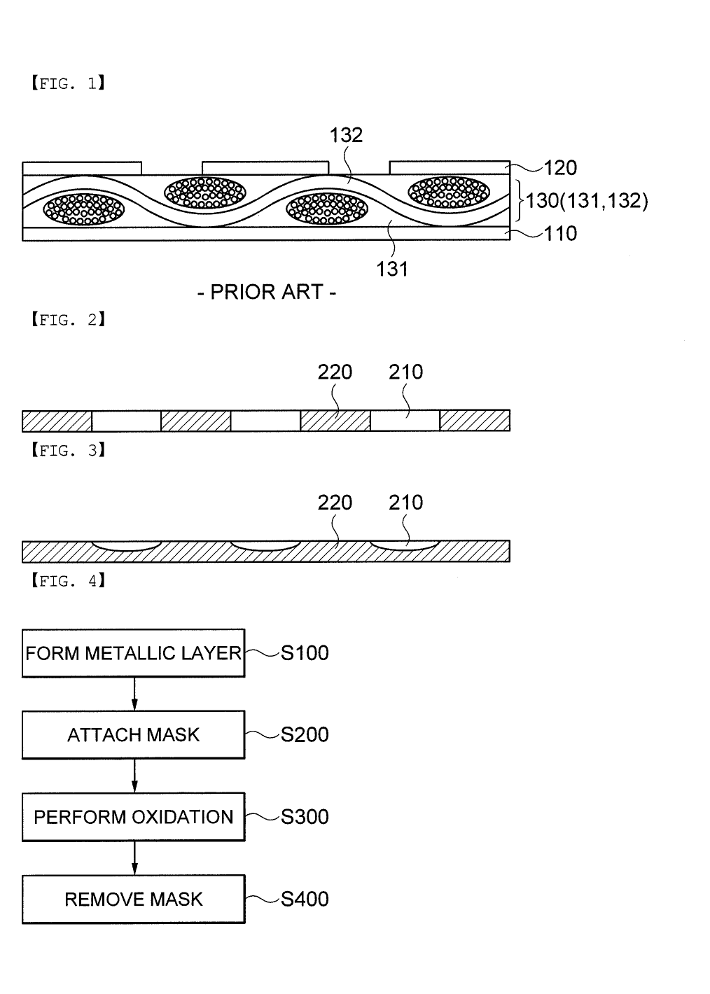

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

FIG. 2 is a cross-sectional view of an electrode pattern according to the present invention.

Referring to FIG. 2, the electrode pattern according to the present invention may include electrode layers 210 having a predetermined pattern and insulators 220 provided between the electrode layers 210.

The electrode layers 210 may be signal layers that transfer electrical signals with various devices or pad layers which are directly adhered to various devices. The electrode layers 210 may be a ground or electrode layers for a power supply.

Therefore, the electrode layers 210 need to be made of metallic materials having excellent electrical conductivity, in particular, metallic materials which may be anodized by an anodizing method or a plasma electrolytic oxidation method. As one example, the electrode layers 210 may contain any one or two or more of aluminum (Al), magnesium (Mg), manganese (Mn), zinc (Zn), titanium (Ti), hafnium (Hf), tantalum (Ta), and niobium (Nb).

As such, since the reason why the electrode layers 210 need to be made of the metallic materials which may be anodized is associated with formation of the insulating layers 220, a description thereof will be made below.

The insulators 220 are provided between the patterns of the respective electrode layers 210 to serve to insulate the electrode layers 210 from each other.

The insulators 220 may be made of the same metallic material as the electrode layers 210, that is, a metal oxide formed by oxidizing an alloy containing any one or two or more of aluminum (Al), magnesium (Mg), manganese (Mn), zinc (Zn), titanium (Ti), hafnium (Hf), tantalum (Ta), and niobium (Nb) which may be anodized.

As one example, the insulators 220 may contain any one or two or more of alumina (Al₂O₃), magnesium oxide (MgO), manganese oxide (MnO), zinc oxide (ZnO), titanium oxide (TiO₂), hafnium oxide (HfO₂), tantalum oxide (Ta₂O₅), and niobium oxide (Nb₂O₃).

As such, the electrode pattern according to the present invention has a structure in which the insulators 220 made of the metal oxide having excellent thermal conductivity are provided between the electrode layers 210 to be adhered to both sides of the electrode layer 210, and as a result, the electrode pattern shows a more excellent heat dissipation effect than the electrode pattern in the related art.

That is, in the electrode pattern according to the present invention, heat generated from various devices (not illustrated) is discharged to the outside even through the insulator 220 which is in adhered to both sides of the electrode layer 210 as well as the bottom of the electrode layer 210. Accordingly, the heat dissipation effect may be significantly improved as compared with the electrode pattern structure in which heat is limitedly moved only by the bottom of the electrode layer.

In the electrode pattern according to the present invention, since the electrode layer 210 is adhered even to the insulators 220 on both sides as well as the bottom, adhesion power may be further increased.

Meanwhile, the electrode layers 210 and the insulators 220 may have thicknesses in the range of several nms to hundreds of μms according to a purpose. In FIG. 2, the electrode layer 210 and the insulator 220 have the same thickness, but the electrode layer 210 may be buried in the insulator 220 with the thickness of the electrode layer 210 being smaller than the thickness of the insulator 220 as illustrated in FIG. 3. In this case, the electrode layer 210 buried in the insulator 220 may have a semicircular shape as illustrated in FIG. 3 and in addition, may have a predetermined shape.

Hereinafter, a method of manufacturing an electrode pattern according to the present invention will be described.

FIG. 4 is a flowchart of a method of manufacturing an electrode pattern according to the present invention.

Referring to FIG. 4, in the method of manufacturing the electrode pattern according to the present invention, forming a metallic layer is first performed (S100).

The metallic layer as a foundation of the electrode layer 210 is made of the metallic materials having excellent electrical conductivity, which may be anodized by the anodizing method or the plasma electrolytic oxidation method.

The metallic layer is formed on a predetermined supporting member, and for example, the metallic layer may be formed on various members such as a core layer or an insulating layer according to a purpose of a substrate and a manufacturing method of a substrate. The present invention is not particularly limited thereto.

The thickness of the metallic layer may be in the range of several nms to 500 μms. When the thickness of the metallic layer is too small, the control is not easy, and as a result, productivity may deteriorate, while when the thickness of the metallic layer is too large, it becomes difficult a minute pattern, and as a result, the metallic layer may have an appropriate thickness.

When the metallic layer is formed, attaching a mask having a predetermined pattern onto the surface of the metallic layer (S200).

Herein, the predetermined pattern formed on the mask may be formed by a general photo process constituted by processes of photoresist application, exposure, etching, photoresist stripping, and the like, and the predetermined pattern is the same as the pattern of the electrode layer 210.

As the mask, dry film resist (DFR) made of a polyester material which is high in heat resistance, acid resistance, and chemical resistance. Only in this case, even in a subsequent oxidation treatment process, since a characteristic is not changed, a stable process may be performed.

After attaching the mask, oxidizing the surface of the metallic layer exposed through an opening other than the pattern in the mask is performed (S300).

As described above, since the predetermined pattern is formed in the mask, when the mask is attached to the metallic layer, a remaining metallic layer region other than a metallic layer region covered by the pattern of the mask is exposed to the outside through the opening other than the pattern.

In this state, when the surface of the metallic layer is oxidized, the metallic layer region exposed through the opening of the mask is oxidized to be chemically changed to the metal oxide, and the metallic layer region covered by the pattern of the mask is not oxidized but keeps its original characteristic. Accordingly, the metallic layer region which is chemically changed to the metal oxide becomes the insulator 220 and the metallic layer region keeping its original characteristic, that is, the electrical conductivity characteristic becomes the electrode layer 210.

In the oxidizing process, the anodizing method or the plasma electrolytic oxidation method may be used. For example, on the assumption that the metallic layer is made of aluminum (Al), the surface of the metallic layer exposed through the opening of the mask reacts with an electrolytic solution and aluminum ions (Al³⁺) are formed on a boundary surface thereof.

In this case, when current density is concentrated by voltage applied to the metallic layer, more aluminum ions (Al³⁺) are formed, and as a result, a plurality of grooves are formed on the surface of the metallic layer exposed through the opening of the mask. Then, oxygen ions O²⁻ are moved to the grooves by force of an electric field to react with the aluminum ions (Al³⁺), and as a result, the metallic layer exposed through the opening of the mask is chemically changed to alumina (Al₂O₃).

After the oxidizing process, lastly, the electrode pattern manufacturing method according to the present invention is terminated by removing the mask by a router or etching (S400).

As such, according to the electrode pattern manufacturing method according to the present invention, the electrode pattern configured by the insulator 220 provided between the electrode layer 210 and the electrode layer 210 may be manufactured by oxidizing one metallic layer according to the predetermined pattern.

That is, in the electrode pattern manufacturing method according to the present invention, since the electrode layer 210 and the insulator 220 having the structure illustrated in FIG. 2 may be simultaneously manufactured by one oxidizing process, the number of processes may be reduced and a production cost may be saved, and as a result, the productivity of the product may be significantly increased.

Hereinafter, a printed circuit board applied with the electrode pattern will be described. However, the printed circuit board is generally called a substrate mounted and printed with various devices and circuits and applied to various kinds of products and may, of course, be a semiconductor substrate other than the printed circuit board or a package structure in which a semiconductor device and a semiconductor chip are mounted and electrode-connected as a wider concept.

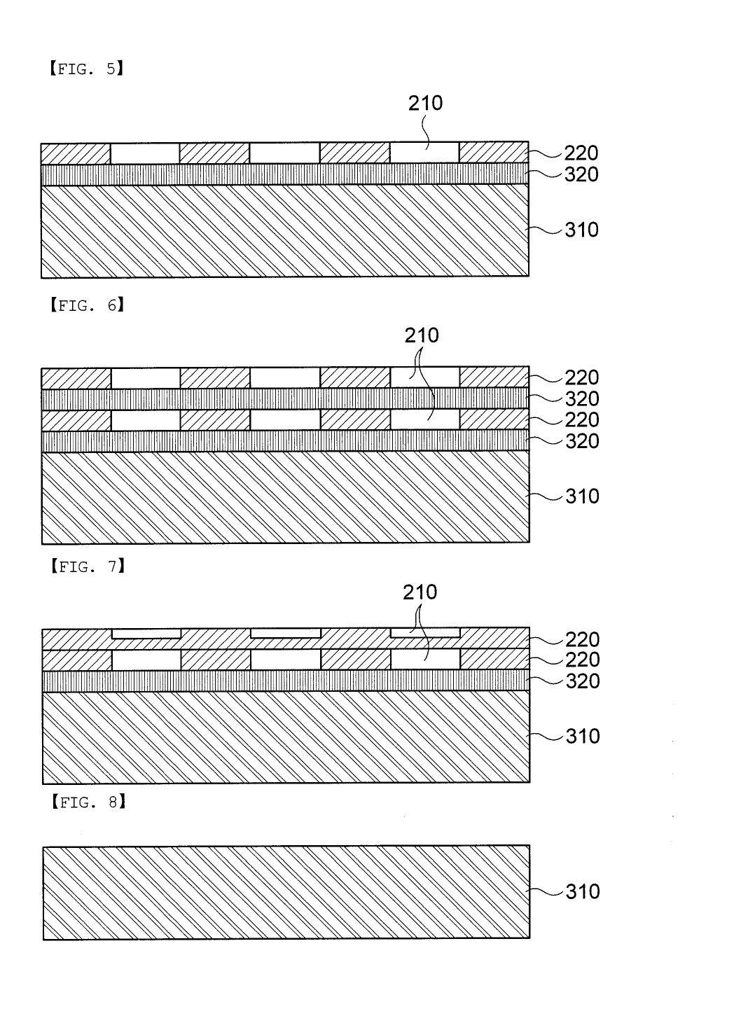

FIG. 5 is a cross-sectional view of the printed circuit board applied with the electrode pattern of the present invention.

Referring to FIG. 5, the printed circuit board applied with the electrode pattern according to the present invention may include insulating layers 320 formed one surface or both surfaces of a mother substrate 310, electrode layers 210 formed on the insulating layers 320 and having a predetermined pattern, and insulators 220 insulating the electrode layers 210 from each other.

Since the printed circuit board applied with the electrode pattern according to the present invention may be a heat dissipation substrate for dissipating the heat generated from the LED or the high-power semiconductor device, the mother substrate 310 needs to be made of a material having excellent thermal conductivity in the exemplary embodiment of the present invention and is not particularly limited in terms of the type thereof.

However, as described below, when the insulating layer 320 is formed by anodizing or plasma electrolytic oxidation, the mother substrate 310 needs to be metal which may be anodized. For example, the mother substrate 310 may contain aluminum (Al), magnesium (Mg), manganese (Mn), zinc (Zn), titanium (Ti), hafnium (Hf), tantalum (Ta), and niobium (Nb), or alloys thereof.

Moreover, when the mother substrate 310 is made of the metallic material, the mother substrate 310 has high rigidity than a substrate configured by a general resin layer, and as a result, the mother substrate 310 is resistant to bending.

The insulating layer 320 formed on one surface or an entire surface of the mother substrate 310 is an insulator that insulates the electrode layer 210 and the mother substrate 310 to prevent the electrode layer 210 and the mother substrate 310 from being electrically short-circuited. The insulating layer 320 may be formed by performing anodizing or plasma electrolytic oxidation of the surface of the mother substrate 310 made of metal in order to achieve higher thermal conductivity.

In this case, the insulating layer 320 is made of metal oxide. For example, on the assumption that the mother substrate 310 is made of aluminum (Al), the insulating layer 320 may be made of alumina (Al₂O₃) formed by anodizing aluminum.

Since alumina (Al₂O₃) is excellent in insulating property and thermal conductivity, an excellent heat dissipation effect is acquired as well as the insulating property is ensured between the mother substrate 310 and the electrode layer 210 even though the thickness of alumina (Al₂O₃) is small. Accordingly, when the insulating layer 320 is made of metal oxide, the thickness of the insulating layer 320 may have an appropriate value in the range of several μms to hundreds of μms according to the purpose of the substrate.

Meanwhile, the insulating layer 320 may be configured by a glass fiber immersed with general epoxy or an epoxy resin added with ceramic filler. However, as described above, since metal oxide such as alumina (Al₂O₃) is more excellent in insulating property and thermal conductivity than the resin, the insulating layer 320 may be made of metal oxide formed by anodizing or plasma electrolytic oxidation.

Besides, since the electrode layers 210 formed on the insulating layer 320 and having the predetermined pattern and the insulators 220 insulating the electrode layers 210 from each other are the same as the electrode pattern, a detailed description thereof will be omitted below.

However, when the printed circuit board applied with the electrode pattern according to the present invention is a multi-layer PCB, the electrode layer 210 and the insulators 220 may be configured in multi-layers. In this case, as illustrated in FIG. 6, the insulating layer 320 is provided between the respective layers in order to insulate the electrode layer 210 of each layer or as illustrated in FIG. 7, in the case of an upper layer, the electrode layer 210 is buried in the insulator 220 by making the electrode layer 210 have a smaller thickness than the insulator 220, and as a result, the electrode layer 210 of each layer may be insulated without the insulating layer. It is apparent that the electrode layers 210 of the respective layers may be electrically connected with each other through vias when the printed circuit board is configured in the multi-layers as illustrated in FIGS. 6 and 7.

In addition, although not illustrated in the figures, when the printed circuit board applied with the electrode pattern according to the present invention is a both-sided PCB, the electrode layer 210 and the insulator 220 may be placed on both surfaces of the mother substrate 310 around the mother substrate 310.

As such, since the printed circuit board applied with the electrode pattern according to the present invention has the structure in which the electrode layer 210 is buried in the insulating layer 320 and the insulator 220 made of metal oxide, the corresponding printed circuit board has still more improved thermal conductivity and adhesion power than a printed circuit board having a general structure.

Meanwhile, when the electrode layer 210 is the pad layer, a plating layer (not illustrated) may be further formed on the surface of the electrode layer 210 so as to be wire-bonded or soldered with the semiconductor device.

The plating layer is made of silver (Au), and in general, the plating layer may be formed by using an electroplating method, or an electroless plating method including electroless nickel immersion gold (ENIG), electroless nickel autocatalytic gold (ENAG), electroless nickel electroless palladium immersion gold (ENEPIG) techniques, and the like.

Hereinafter, a method of manufacturing the printed circuit board applied with the electrode pattern according to the present invention will be described.

FIGS. 8 through 12 are flowcharts of the method of manufacturing the printed circuit board applied with the electrode pattern of the present invention. First, preparing the mother substrate 310 is performed as illustrated in FIG. 8.

The material of the mother substrate 310 is not particularly limited, but when the insulating layer 320 is formed by performing anodizing or plasma electrolytic oxidation of the mother substrate 310 as in a subsequent process, the mother substrate 310 may contain metal which may be anodized.

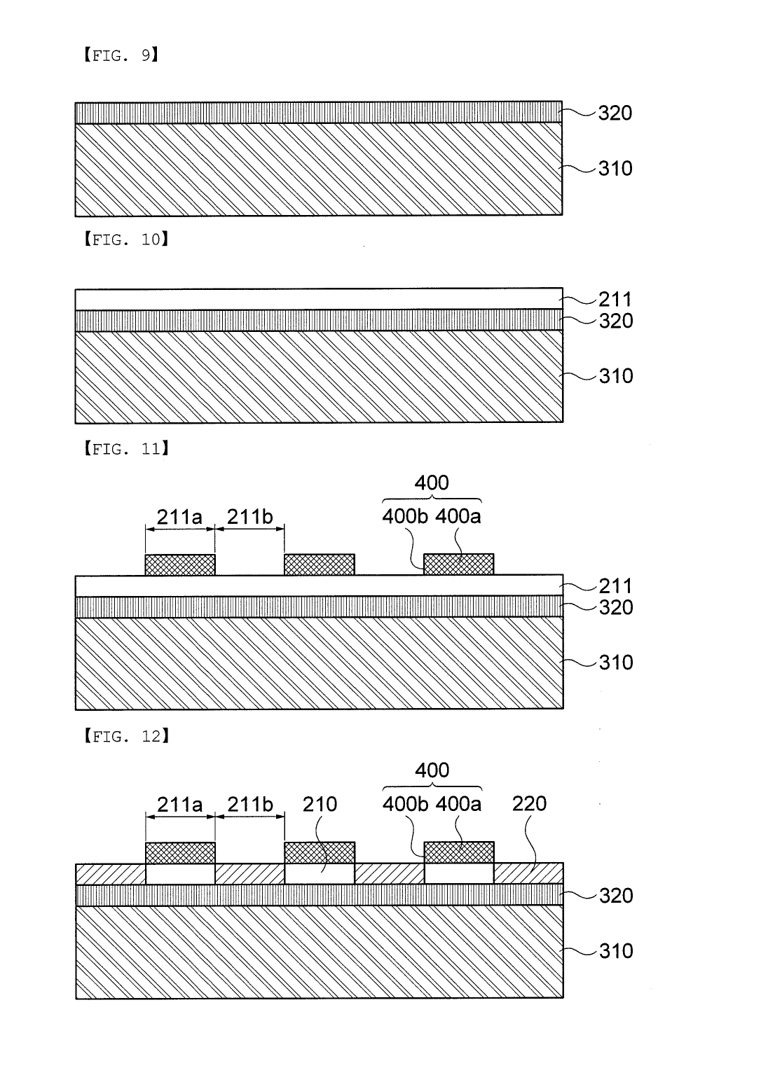

Thereafter, as illustrated in FIG. 9, forming the insulating layer 320 on one surface or both surfaces of the mother substrate 310 is performed.

The insulating layer 320 may be formed by bonding a sheet in which epoxy is immersed in the glass fiber or an epoxy sheet added with ceramic filler, but is preferably formed by performing anodizing or plasma electrolytic oxidation of the mother substrate 310 made of metal in terms of the thermal conductivity.

When the insulating layer 320 is formed, forming a metallic layer 211 on the insulating layer 320 is performed as illustrated in FIG. 10.

The metallic layer 211 as a foundation of the electrode layer 210 is made of the metallic materials having excellent electrical conductivity, which may be anodized by the anodizing method or the plasma electrolytic oxidation method.

As the method of forming the metallic layer 211, any one of general known deposition methods including sputtering, plating, thermal deposition, e-beam deposition, physical vapor deposition (PVD), chemical vapor deposition (CVD), and the like may be used.

Next, as illustrated in FIG. 11, attaching a mask 400 having a predetermined pattern 400a onto the surface of the metallic layer 211 is performed.

Herein, the predetermined pattern 400a formed on the mask 400 may be formed by a general photo process and is the same as a pattern of the electrode layer formed in a subsequent process.

In order to increase adhesion power of the mask 400, a process to give roughness to the surface of the metallic layer 211 may be additionally performed, before attaching the mask 400.

Thereafter, as illustrated in FIG. 12, oxidizing a metallic layer region 211b exposed through an opening 400b, which is other than the pattern 400a in the mask 400 is performed.

Since the predetermined pattern 400a is formed in the mask 400, when the mask 400 is attached onto the metallic layer 211, the metallic layer region 211b other than a metallic layer region 211a covered by the pattern 400a is exposed to the outside through the opening 400b.

In this state, when the metallic layer 211 is oxidized, the metallic layer region 211b is oxidized to be the insulator 220 (see FIG. 5) made of metal oxide and the metallic layer region 211a is not oxidized and becomes the electrode layer 210 (see FIG. 5).

In the oxidizing process, the anodizing method or plasma electrolytic oxidation method may be used, and since the description thereof is made above, a detailed description thereof will be omitted.

After the oxidation, lastly, when the mask 400 is removed by the router or etching, the printed circuit board of FIG. 5 is finally completed.

Meanwhile, when the electrode layers 210 and the insulators 220 are built up by repeatedly performing the steps of FIGS. 10 through 12, the multi-layer printed circuit board applied with the electrode pattern according to the present invention may be manufactured.

As set forth above, according to the exemplary embodiments of the present invention, since the electrode pattern can be formed by a simple process, a production cost is saved and productivity of a product is improved.

The electrode layer is buried, and as a result, the adhesion power between the insulating layer and the electrode layer is increased, thereby improving reliability of the product.

A movement route of heat is widened to show an excellent heat dissipation effect.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. An electrode pattern, comprising:
electrode layers having a predetermined pattern; and
insulators insulating the electrode layers from each other,
wherein the insulators are made of metal oxide.

2. The electrode pattern according to claim 1, wherein the insulators are made of metal oxide formed by oxidizing the same material as the electrode layers.

3. The electrode pattern according to claim 1, wherein the insulators are regions oxidized in a metallic layer, and the electrode layers are regions not oxidized in the metallic layer.

4. The electrode pattern according to claim 1, wherein the insulators contain any one or two or more of alumina (Al₂O₃), magnesium oxide (MgO), manganese oxide (MnO), zinc oxide (ZnO), titanium oxide (TiO₂), hafnium oxide (HfO₂), tantalum oxide (Ta₂O₅), and niobium oxide (Nb₂O₃).

5. The electrode pattern according to claim 1, wherein the electrode layer is a metallic material which is anodized.

6. The electrode pattern according to claim 5, wherein the electrode layers contain any one or two or more of aluminum (Al), magnesium (Mg), manganese (Mn), zinc (Zn), titanium (Ti), hafnium (Hf), tantalum (Ta), and niobium (Nb).

7. The electrode pattern according to claim 1, wherein the electrode layer has the same thickness as the insulator.

8. The electrode pattern according to claim 1, wherein the electrode layer has a smaller thickness than the insulator and thus, the electrode layer is provided to be buried in the insulator.

9. The electrode pattern according to claim 8, wherein the electrode layer buried in the insulator has a semi-circular shape.

10. A method of manufacturing an electrode pattern, comprising:
forming a metallic layer;
attaching a mask with a predetermined pattern onto the surface of the metallic layer;
forming electrode layers and insulators insulating the electrode layers from each other by oxidizing the metallic layer exposed through an opening on the mask; and
removing the mask.

11. The method according to claim 10, wherein the predetermined pattern formed on the mask is the same as a pattern of the electrode layer.

12. The method according to claim 10, wherein the predetermined pattern of the mask is formed through a photo process.

13. The method according to claim 10, wherein the metallic layer is made of a metallic material which is anodized.

14. The method according to claim 13, wherein the metallic layer contains any one or two or more of aluminum (Al), magnesium (Mg), manganese (Mn), zinc (Zn), titanium (Ti), hafnium (Hf), tantalum (Ta), and niobium (Nb).

15. The method according to claim 10, wherein the metallic layer is formed by any one process of sputtering, plating, thermal deposition, e-beam deposition, physical vapor deposition (PVD), and chemical vapor deposition (CVD).

16. The method according to claim 10, wherein the oxidizing uses an anodizing method or a plasma electrolytic oxidation method.

17. A printed circuit board, comprising:
a mother substrate;
an insulating layer formed on one surface or both surfaces of the mother substrate;
electrode layers formed on the insulating layer and having a predetermined pattern; and
insulators insulating the electrode layers from each other,
wherein the insulators are made of metal oxide.

18. The printed circuit board according to claim 17, wherein the mother substrate is made of a metallic material which is anodized.

19. The printed circuit board according to claim 17, wherein the insulating layer is made of metal oxide.

20. The printed circuit board according to claim 17, wherein the insulators insulating the electrode layers from each other are configured in multilayers, and the insulating layers are provided between the respective layers.

21. The printed circuit board according to claim 17, wherein the insulators insulating the electrode layers from each other are configured in the multilayers, and the electrode layer positioned on the top is thinner than the insulator to be buried in the insulator.

22. A method of manufacturing a printed circuit board, comprising:
(a) preparing a mother substrate;
(b) forming an insulating layer on one surface or both surfaces of the mother substrate;
(c) forming a metallic layer on the insulating layer;
(d) attaching a mask with a predetermined pattern onto the surface of the metallic layer;
(e) forming electrode layers and insulators insulating the electrode layers from each other by oxidizing the metallic layer exposed through an opening on the mask; and
(f) removing the mask.

23. The method according to claim 22, wherein the insulating layer is formed by oxidizing the mother substrate.

24. The method according to claim 22, further comprising building up an electrode pattern by repeatedly performing steps (b) to (f), after the removing of the mask.
